(19) United States
(12) Patent Application Publication
(10) Pub. No.: US 2015/0099116 A1
(43) Pub. Date: Apr. 9, 2015

(54) CHIRAL STRUCTURE, METHOD OF MAKING A CHIRAL STRUCTURE, AND ROLLED-UP STRUCTURE WITH MODULATED CURVATURE

(71) Applicant: The Board of Trustees of the University of Illinois, Urbana, IL (US)

(72) Inventors: Xiuling Li, Champaign, IL (US); Paul J. Froeter, Urbana, IL (US); Kuen J. Hsia, Champaign, IL (US); Wen Huang, Champaign, IL (US)

(21) Appl. No.: 14/509,656

(22) Filed: Oct. 8, 2014

Related U.S. Application Data
(60) Provisional application No. 61/888,833, filed on Oct. 9, 2013.

(51) Int. Cl. C30B 29/66; C30B 29/38; C30B 33/10

(52) U.S. Cl. CPC C30B 29/66; C30B 33/10; C30B 29/38
USPC 428/371; 216/36; 423/344; 106/286.8

(57) ABSTRACT

A chiral structure comprises an elongate strip in a rolled configuration about a longitudinal axis, where the rolled configuration is a helical configuration comprising a non-zero helix angle. The elongate strip comprises an amorphous or a polycrystalline material. A rolled-up structure with modulated curvature comprises a sheet comprising an amorphous or polycrystalline material in a rolled configuration about a longitudinal axis, where the sheet comprises a thickness t and the rolled configuration comprises an inner diameter D. An inner diameter-to-thickness ratio D/t of the rolled-up structure is no greater than about 40.

### RELATED APPLICATIONS

The present patent document claims the benefit of priority under 35 U.S.C. §119(e) to U.S. Provisional Patent Application Ser. No. 61/888,833, filed on Oct. 9, 2013, which is hereby incorporated by reference in its entirety.

Also incorporated by reference in their entirety are U.S. Nonprovisional patent application Ser. No. 14/051,188, U.S. Nonprovisional patent application Ser. No. 14/051,192, and U.S. Nonprovisional patent application Ser. No. 14/051,208, which were filed on Oct. 10, 2013, and claim priority to the above-mentioned provisional patent application.

### FEDERALLY SPONSORED RESEARCH OR DEVELOPMENT

This invention was made with government support under contract number ECCS 1309375 awarded by the National Science Foundation and contract number DE-F002-07ER46471 awarded by the Department of Energy. The government has certain rights in the invention.

### TECHNICAL FIELD

The present disclosure is directed generally to rolled-up structures formed by strain-induced roll-up of thin films, and more particularly to chiral structures.

### BACKGROUND

Strain-induced self-rolled-up thin films or membranes have attracted great interest for potential applications in optics, electronics, and biology. Self-rolled-up tubes were first fabricated by Prinz et al. (Physica E, 6, 828 (2000)) by releasing a strained InAs/GaAs bilayer from a GaAs substrate using an AIAs sacrificial layer, wherein rolling is driven by a momentum generated between the oppositely strained InAs and GaAs layers. Since then, self-rolled-up tubes made of other materials and having precisely controlled 3D tubular architectures have been demonstrated through deposition by metalorganic chemical vapor deposition (MOCVD), molecular beam epitaxy (MBE), and plasma enhanced chemical vapor deposition (PECVD). Various sacrificial layers have been successfully used for the formation of the tubular structures, constrained primarily by the etching selectivity of the sacrificial layer to the strained thin film during the final release process. Depending on the material system and the desired tube dimensions, thin films can be patterned into fully functional devices using conventional lithography before releasing (and rolling-up), and the resulting rolled-up structures may exhibit improved performance due to 3D physical, electronic, or electromagnetic confinement effects.

### BRIEF SUMMARY

A chiral structure comprises an elongate strip in a rolled configuration about a longitudinal axis, where the rolled configuration is a helical configuration comprising a non-zero helix angle. The elongate strip comprises an amorphous or a polycrystalline material.

A method of making a chiral structure comprises forming an elongate strip on a supporting surface of a substrate. The elongate strip comprises an amorphous or polycrystalline material and includes an upper portion under tensile stress and a lower portion nearer to the substrate under compressive stress. A portion of the substrate is etched, thereby releasing an end of the elongate strip and allowing the elongate strip to roll up to relieve strain. A rolled-up chiral structure comprising the elongate strip in a rolled configuration about a longitudinal axis is formed, where the longitudinal axis is substantially parallel to the supporting surface and the rolled configuration is a helical configuration comprising a non-zero helix angle.

A rolled-up structure comprises a sheet comprising an amorphous or polycrystalline material in a rolled configuration about a longitudinal axis, where the sheet comprises a thickness t and the rolled configuration comprises an inner diameter D. An inner diameter-to-thickness ratio D/t of the rolled-up structure is no greater than about 40.

### BRIEF DESCRIPTION OF THE DRAWINGS

FIGS. 1A-1B show an exemplary strained bilayer comprising a top sublayer in tension and a bottom sublayer in compression deposited on a sacrificial layer on a substrate, and FIGS. 1C-1D show schematically the release and subsequent roll-up of the bilayer from the underlying sacrificial layer.

FIG. 2A shows a scanning electron microscope (SEM) image of an array of 4.4 micron-diameter tubes rolled from SiNₓ sheets, and the inset shows a single tube at a high magnification; FIG. 2B shows a plot of tube inner diameter as a function of the thickness of the compressive (LF) and tensile (HF) SiNₓ layers, where the spheres represent experimental data and the triangles represent calculated data.

FIG. 3A shows a ladder geometry where all parameters a through e are defined as labeled, and FIGS. 3B-3C show tilted SEM images of chiral structures having left-handed (B) and right-handed (C) chirality.

FIG. 4 shows an exemplary chiral structure on a substrate.

FIG. 5 is a SEM image showing partially etched ladder structures prior to rolling.

FIG. 6A is a SEM image of a SiNₓ tubular structure after annealing an as-rolled sheet to reduce the diameter, FIG. 6B is a SEM image of an array of tapered SiNₓ structures created by a non-equilibrium anneal of as-rolled sheets; and FIG. 6C is a SEM image of a single tapered SiNₓ structure formed by a non-equilibrium anneal.

FIGS. 7A-7E are schematics illustrating finite element modeling (FEM) simulations of the roll-up of a strained layer comprising a SiNₓ bilayer.

FIG. 8A shows a ladder geometry prior to roll-up (left) and the simulated rolled-up structure (upper right) in comparison with experimental results (lower right); FIG. 8B shows how anisotropic etching of a ladder structure can be represented with FEM simulations.

### DETAILED DESCRIPTION

Described herein are rolled-up micro- and nanoscale chiral structures that can be fabricated with a controlled chirality. Also described are rolled-up structures that have a modulated diameter to a novel post-processing treatment.

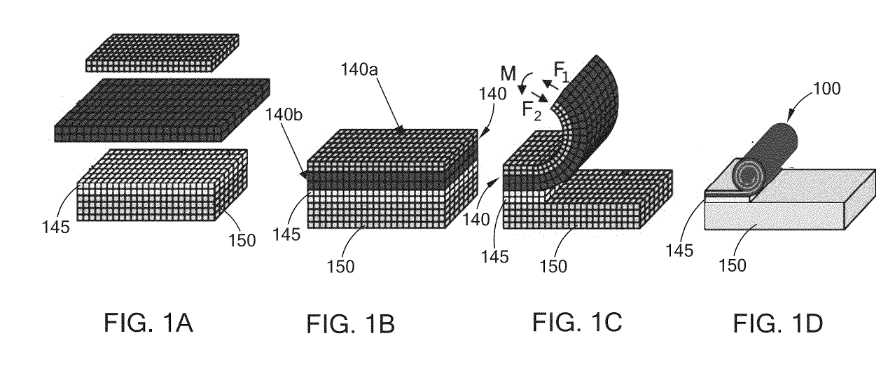

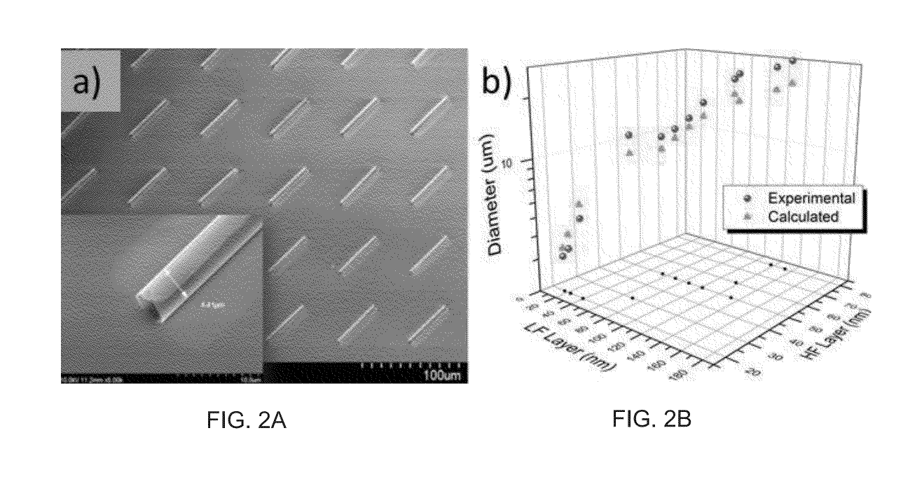

First, an introduction to the self-rolling concept is provided in reference to FIGS. 1A-1D. Rolled-up micro- and nanotubular device structures form spontaneously when strained planar sheets or membranes deform as a consequence of energy relaxation. A strained sheet may comprise an oppositely strained bilayer 140 (e.g., a top layer 140a in tension on a bottom layer 140b in compression), which may be in contact with a sacrificial layer 145 on a substrate 150. The oppositely strained bilayer 140 may be released from the substrate 150 when the sacrificial layer 145 is etched away. Once released, the opposing strain within the bilayer 140 generates a net momentum, driving the planar sheet to roll up into a tubular spiral structure 100. The scanning electron microscope (SEM) images of FIG. 2A show an array of 4.4 micron-diameter rolled-up tubular structures and a single rolled-up tube at a higher magnification (inset). The sheet and rolled-up structure of this example comprises non-stoichiometric silicon nitride (SiNₓ).

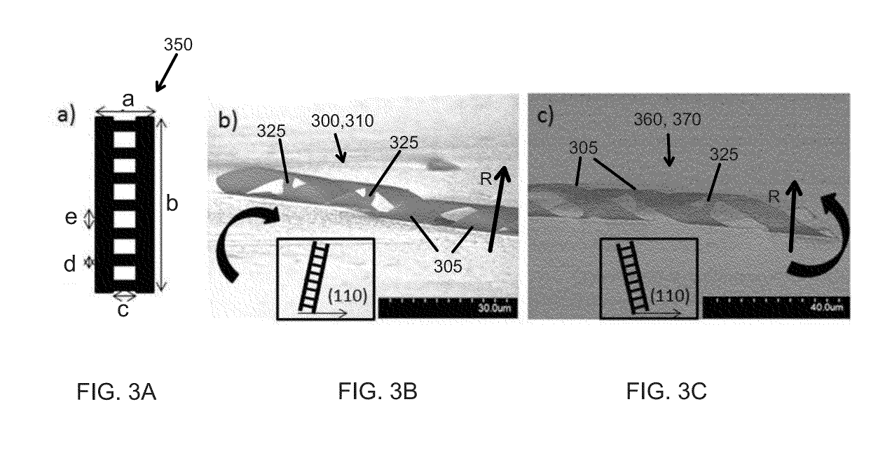

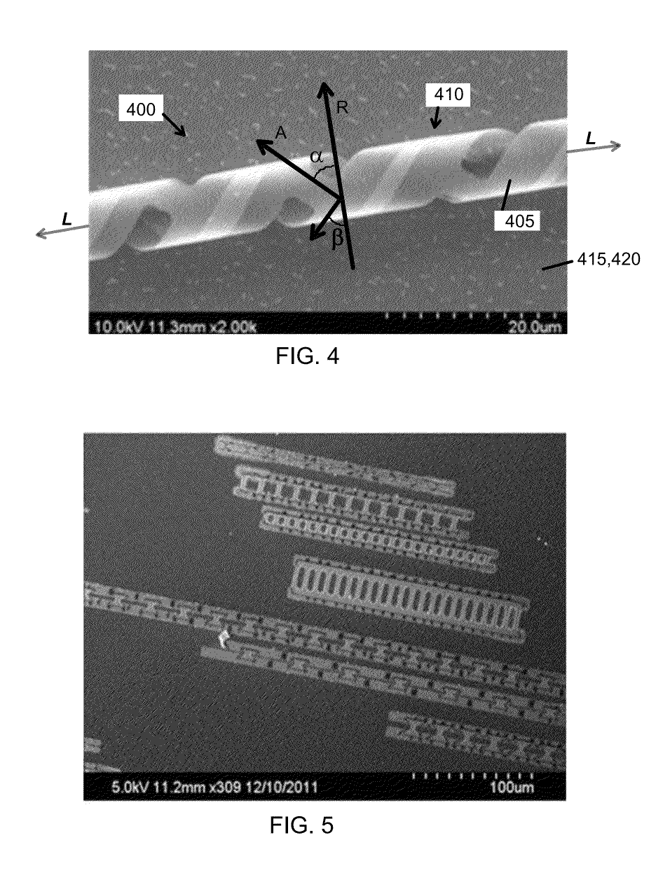

Under certain conditions, it is possible to form rolled-up structures that include a controlled amount of chirality. Exemplary chiral structures are shown in FIGS. 3B-3C and FIG. 4. Referring first to FIG. 4, the chiral structure 400 comprises an elongate strip 405 in a rolled configuration 410 about a longitudinal axis L, where the rolled configuration 410 is a helical configuration that (by definition) includes a non-zero helix angle β. The chiral structure 400 may be disposed on a supporting surface 415 of a substrate 420 such that the longitudinal axis L is substantially parallel to the supporting surface 415.

It may be advantageous for the elongate strip 405 to have isotropic mechanical properties prior to rolling, at least in a plane parallel to the supporting surface 415 of the substrate 420, so that the rolling direction R may be determined or at least influenced by the crystallography of the underlying substrate 420. Accordingly, it may be preferred for the elongate strip 405 to have an amorphous or a non-textured polycrystalline microstructure.

The substrate 420 may be a single crystal substrate comprising a crystallographic plane oriented parallel to the supporting surface and having a preferred etch direction. For a chiral structure formed on (rolled up on) the single crystal substrate, the rolling direction R of the chiral structure may be substantially parallel to the preferred etch direction of the single crystal substrate. As would be known by one of ordinary skill in the art, the preferred etch direction is the crystallographic direction along which etching preferentially occurs when the single crystal is exposed to a suitable chemical etchant. The rolling direction of the rolled configuation may thus be predetermined based on the crystallography of the underlying substrate. The single crystal substrate may be a single crystalline bulk substrate that includes an etched surface portion along the preferred etch direction after roll-up. It is also possible for the single crystal substrate to include a single crystalline sacrificial layer thereon that is partially or entirely removed along the preferred etch direction during roll-up.

Alternatively, the substrate 420 may be an amorphous substrate or a polycrystalline substrate that does not have a crystallographically preferred etch direction. While etching may still be employed to release the elongate strip to form the rolled configuration, the direction of etching and thus the geometry of the resulting rolled-up structure may be less predictable and/or may depend on other parameters, as discussed below. In this embodiment, as in the previous embodiment, a portion of the substrate may be etched to facilitate roll-up of the elongate strip(s), or the substrate may comprise a sacrificial layer that is removed during roll-up.

As would be understood by one of ordinary skill in the art, (hkl) notation is used herein in reference to a crystallographic plane of a particular orientation from the {hkl} family of crystallographically equivalent planes. Similarly, [hkl] notation is used in reference to a particular crystallographic direction, and <hkl> notation is used in reference to one or more crystallographically equivalent directions. For example, the (100) plane and the (001) plane are part of the {100} family of planes for crystals with cubic symmetry, and [01-1] and [0-11] are particular <110> directions. As used herein, the term “(hkl) substrate” or “hkl layer” refers to a substrate or layer having its (hkl) crystallographic planes oriented parallel to a surface of the substrate or layer. For example, a (100) substrate has its (100) crystallographic planes oriented parallel to the surface. In another example, a (111) sacrificial layer has its (111) crystallographic planes oriented parallel to the surface.

When a single crystal substrate is employed, the crystallographic plane oriented parallel to the supporting surface of the substrate may be selected from the {111} family of planes, the {110} family of planes, or from the {100} family of planes. The preferred etch direction may be a <110> direction, a <100> direction, or a <111> direction. For example, in the case of a silicon (111) substrate, which has a (111) plane oriented parallel to the supporting surface, the preferred etch direction may be a <110> direction.

The chirality of the chiral structure 400, as represented by the helix angle β defined with respect to the rolling direction R, may be predetermined based on the orientation of the elongate strip 405 on the supporting surface 415 of the substrate 420 prior to rolling. Referring again to FIG. 4, a misalignment angle α may be defined as the orientation of the long axis A of the elongate strip 405 with respect to the rolling direction R prior to rolling. A misalignment angle α of zero means the long axis A of the elongate strip 405 is aligned with the rolling direction R; a misalignment angle α of 90° means the long axis A of the elongate strip 405 is perpendicular to the rolling direction R; in both of these cases, the helix angle β is zero. As explained above, the rolling direction R may correspond to the preferred etch direction of a single crystal substrate (either a bulk substrate or sacrificial layer). The misalignment angle α of the elongate strip 405 prior to rolling may have the same value as the helix angle β of the chiral structure 400 after rolling. A positive or clockwise misalignment angle α leads to a chiral structure having left-handed chirality, while a negative or counterclockwise misalignment angle α a leads to a chiral structure having right-handed chirality. For a rolled structure having some amount of chirality, the absolute value of the helix angle β and the absolute value of the misalignment angle α are greater than zero and, more specifically, may be from about 1° to less than 90°. Preferably, the absolute value of the misalignment angle α and the helix angle β are each about 5° or greater, about 10° or greater, about 15° or greater, about 20° or greater, or about 25° or greater. Typically, neither the misalignment angle α nor the helix angle β are greater than about 70°, greater than about 50°, greater than about 30°, or greater than about 20°. As will be discussed further below, it may be advantageous for the absolute value of the misalignment angle α to be from about 10° to about 20°, or from about 12° to about 18°.

The chirality of the chiral structure may also or alternatively be influenced by the aspect ratio (length-to-width ratio) of the elongate strip prior to rolling. The aspect ratio may be a particularly important parameter when the underlying substrate is amorphous or polycrystalline (with isotropic properties) and thus does not have a preferred etch direction. In such a case, for aspect ratios of about 3:1 or less, the rolled configuration may exhibit no chirality; that is, the helix angle may be zero. For aspect ratios greater than 3:1, for example, aspect ratios of 4:1 or more, 6:1 or more, 9:1 or more, 10:1 or more, 12:1 or more 15:1 or more, 20:1 or more, or 30:1 or more, the rolled configuration may exhibit a significant amount of chirality, where the chirality (as exhibited by the absolute value of the helix angle) may increase as the aspect ratio of the elongate strip increases. Typically, the aspect ratio is not greater than about 50:1. When the chiral structure is formed from more than one adjacent elongate strip, such as the ladder structure described below, the aspect ratio may be determined based on the total width of the structure (e.g., the width of each elongate strip plus any spacing therebetween). Exemplary unrolled ladder structures are shown in FIG. 3A and FIG. 5 and will be described further below.

The elongate strip 405 comprises a strain-relieved layer that includes less strain (or no strain) in the rolled configuration than in an unrolled (or planar) configuration prior to rolling. The strain-relieved layer may comprise one or more sublayers that are at least partially relieved of strain as a consequence of rolling. Accordingly, what is referred to as a strain-relieved layer in the rolled configuration may be referred to as a strained layer in the unrolled configuration.

In the example of FIGS. 1A-1D, the strain-relieved layer (and the strained layer) may comprise two sublayers, which may be referred to as a bilayer. Specifically, the strained layer or bilayer 140 may comprise a top sublayer 140a in tension and a bottom sublayer 140b in compression to facilitate the rolling up shown schematically in FIGS. 1C-1D. The bilayer 140 may thus be referred to as an oppositely strained bilayer. The strain-relieved layer and the strained layer typically comprise an amorphous or polycrystalline material (preferably an untextured polycrystalline material); in some cases, however, a single crystal material may be used.

The elongate strip 405 may comprise any of a number of materials, particularly inorganic materials such as silicon nitride, silicon oxide, aluminum oxide, boron nitride, magnesium oxide, silicon, chromium, gold and/or titanium. For example, the elongate strip may comprise non-stoichiometric silicon nitride (SiNₓ, where x may have a value from about 0.5 to about 1.5), which may be amorphous, or stoichiometric silicon nitride (e.g., Si₃N₄, Si₂N, SiN or Si₂N₃). The strip may also or alternatively include another material, such as an elemental or compound semiconducting material or a polymer. For example, single crystal films such as InAs/GaAs, InGaAs/GaAs, InGaAsP/InGaAsP, Si—Ge/Si may in some cases be used to form the elongate strip.

The strain in the elongate strip may be introduced by compositional or structural differences between sublayers that are successively deposited (e.g., by chemical vapor deposition) so as to be in contact with each other. For example, in the case of a single crystal strained layer, adjacent contacting sublayers (e.g., top and bottom sublayers) may be formed with different lattice parameters and/or with different stoichiometries. To facilitate rolling up upon release from an underlying sacrificial layer 145 deposited on a substrate 150, the top sublayer 140a may may have a smaller lattice parameter than the bottom sublayer 140b, as shown schematically in FIG. 1A for the exemplary single crystal sublayers. In such a circumstance, the top sublayer 140a comprises a residual tensile stress, and the bottom sublayer 140b comprises a residual compressive stress. The residual stress profile in the sublayers 140a, 140b may be reversed (compressive on top; tensile on bottom) in order to having the rolling proceed downward, instead of upward, which is possible for any of the embodiments described herein. It is also possible that a single layer may be formed with appropriate compositional and/or structural gradients through the thickness of the layer to produce the desired stress profile in the sheet or elongate strip.

Films deposited by plasma-enhanced chemical vapor deposition (PECVD) differ from single crystal films in that internal strain may not be developed by crystal lattice mismatch but rather by density differences and thermal mismatch achieved by appropriate deposition conditions. For example, amorphous SiNₓ films deposited under high frequency (HF) conditions (e.g., at 13.56 MHz) may exhibit tensile strains, while films deposited under low frequency (LF) conditions (e.g., at 380 kHz) are naturally compressively strained. Thus, oppositely strained bilayer (LF/HF) deposition can be achieved using a single deposition tool. In the case of SiNₓ deposited through PECVD using ammonia/silane mixtures, the gas ratio of NH₃/SiH₄ can be adjusted to obtain a high amount of amine fragments in the film, which can result large amounts of compressive strain in the film and thus yield a smaller diameter chiral or tubular structure upon roll-up.

It has been demonstrated experimentally that thin films deposited by different methods or under different conditions may provide a strained layer having adjustable values of residual stress in a wide range, such as from 478 to −1100 MPa for silicon nitride (SiNₓ) and from greater than 1000 MPa to less than −1000 MPa for metal thin films on SiO₂, where positive values of residual stress correspond to tensile stresses, and negative values correspond to compressive stresses. By carefully designing the residual stress mismatch in each sublayer, it is possible to generate a large enough driving force to overcome resistance and to continue rolling over a long enough distance to form as many turns as needed. To create a higher residual stress mismatch during deposition of the strained SiNₓ layers, for example, and thus a smaller chiral structure diameter, the PECVD environment may be changed by adjusting a ratio of the SiH₄ flow rate to the NH₃ flow rate, as indicated above, or by optimizing the power of the RF source. The tensile and compressive strains for the exemplary strained layers described herein are 407 MPa and −1167 MPa, respectively.

As indicated above, the chiral structure 300,360 may comprise two or more adjacent elongate strips 305 connected by a series of transverse strips 325, where the rolled configuration 310,370 comprises a double helical configuration, as shown in FIGS. 3B and 3C. Prior to rolling, the adjacent elongate strips 305 may be described as having a ladder structure or ladder geometry. The rolled configuration 310,370 may viewed as analogous to the double helix structure of DNA, where the rungs or transverse strips 325 of the ladder geometry correspond to DNA base pairs.

FIG. 3A shows an exemplary ladder structure 350 of total width a and length b that may be made of nonstoichiometric silicon nitride (SiNₓ). The dimensions of the transverse strips (or rungs) are given by width c, height d, and spacing between rungs e. As with tubular rolled-up structures that have no chirality, the curvature of the rolled-up structures may be determined by the embedded strain. The amount of overlap or the spacing from turn-to-turn (pitch) and the chirality may be determined by the ladder geometry and misalignment angle with respect to the rolling direction.

Shown in FIGS. 3B and 3C are two exemplary rolled-up SiNₓ ladder structures that have a double helical configuration with complementary rotations (left-handed for B and right-handed for C). These complementary structures may be achieved by orienting the adjacent strips (a=20 μm, b=204 μm, c=6 μm, d=3 μm, and e=20 μm) at a misalignment angle of ±15° relative to a <110> direction of the underlying substrate, which also corresponds to the rolling direction R.

Generally speaking, the length b of the elongate strip(s) may be at least about 10 microns, at least about 20 microns, at least about 40 microns, at least about 60 microns, at least about 80 microns, at least about 100 microns, or at least about 150 microns. Typically, the length b is no greater than about 2 mm, no greater than 1 mm, no greater than about 500 microns, no greater than 300 microns, or no greater than about 200 microns. For example, b may range from about 100 microns to about 600 microns, or from about 200 microns to about 500 microns.

The elongate strip(s) may have a width a which is equal to the width of the elongate strip when only a single elongate strip is rolled up or is equal to the total width of the ladder (or grid) structure when two or more adjacent elongate strips are rolled up, as illustrated for example in FIG. 3A. Generally speaking, the dimension a may lie between about 1 micron and 300 microns, and is more typically between about 1 micron and about 100 microns, or between about 1 micron and about 20 microns. While it may be advantageous for the elongate strip to have an aspect ratio (length-to-width) of greater than 1 or much greater than 1, it is also contemplated that the aspect ratio may be equal to 1 or less than 1. Depending on the aspect ratio, the elongate strip may be better described as a sheet in some embodiments.

Suitable exemplary values for c, d and e are shown in Table 1. Generally speaking, the dimension c may lie between 1 micron and 30 microns, between 1 micron and 20 microns, or between 1 micron and 10 microns. The dimension d may lie between about 1 micron and 20 microns, between about 1 micron and 10 microns, or between about 1 micron and 5 microns. The dimension e may lie between about 5 microns and 200 microns, between about 5 microns and 100 microns, or between about 5 microns and about 50 microns.

Typically, the elongate strip has a thickness of from about 10 nm to about 1 micron (1,000 nm); however, in some embodiments (e.g., in which single crystals may be used), the thicknesses may be about 1 nm or less, down to a few atomic monolayers or to one atomic monolayer. Generally, the thickness is at least about 10 nm, at least about 30 nm, at least about 50 nm, at least about 75 nm, or at least about 100 nm. The thickness may also be no more than about 1 micron, no more than about 800 nm, no more than about 600 nm, no more than about 400 nm, or no more than about 200 nm. When a large number of turns is required and the strained layer (e.g., elongate strip or sheet) includes two oppositely strained sublayers (a bilayer), it may be advantageous for the sublayers to have the same thickness.

The inner diameter of the rolled configuration depends on the thickness of the elongate strip as well as the amount of strain in the elongate strip prior to rolling. A thicker elongate strip may tend to roll to a larger inner diameter; however, a higher level of strain can offset this effect, since the inner diameter (D) of the rolled configuration is proportional to the thickness (t) of the elongate strip and is inversely proportional to the amount of strain (ε) therein (D∝t/ε). FIG. 2B shows a plot of inner diameter as a function of the strained layer thickness for a SiNₓ sheet, specifically the thicknesses of the compressive (LF) and tensile (HF) layers. The spheres represent experimental data and the triangles represent calculated data.

The rolled configuration of the elongate strip may have a diameter (inner diameter) of from about 1 micron to about 50 microns, from about 10 microns to about 30 microns, or from about 3 microns to about 8 microns. Typically, the inner diameter of the rolled configuration is no more than about 50 microns, no more than about 30 microns, no more than about 20 microns, or no more than about 10 microns. The inner diameter may also be at least about 1 micron, at least about 4 microns, or at least about 8 microns. However, in some embodiments, such as when the elongate strip comprises a single crystal film, the inner diameter of the rolled configuration may be significantly smaller due to the reduced strip thickness. For example, the inner diameter may be no more than 100 nm, no more than 40 nm, no more than 10 nm, or no more than 5 nm, and typically the inner diameter is at least about 1 nm. Furthermore, the inner diameter may be reduced after rolling by the annealing method described below, so as to achieve unprecedented inner diameter-to-thickness ratios.

Depending on (a) the length of the elongate strip, (b) the thickness t of the elongate strip, (c) the amount of strain ε in the elongate strip prior to rolling, and (d) the misalignment angle α, the rolled configuration may include at least about 5 turns, at least about 10 turns, at least about 20 turns, at least about 40 turns, at least about 60 turns, or at least about 80 turns. Typically, the rolled configuration includes no more than about 120 turns, or no more than about 100 turns. For example, the number of turns may range from about 20 turns to about 80 turns, or from about 40 turns to about 60 turns.

The rolled configuration of the chiral structure has a length along the longitudinal axis that depends on the length of the elongate strip and the helix angle. Typically, the length is at least about at least about 50 microns, at least about 100 microns, at least about 300 microns, at least about 500 microns, at least about 800 microns, or at least about 1000 microns, and the length may also be about 3000 microns or less, about 2000 microns or less, or about 1000 microns or less. For example, the length may range from about 300 microns to about 3000 microns, or from about 500 microns to about 2000 microns, or from about 500 microns to about 1000 microns.

The sacrificial layer, which may be (a) an additional layer on the substate between the strained layer and the substrate that is removed during roll-up, or (b) a portion of the substrate adjacent to the strained layer that is removed during roll-up, may comprise a material that can be etched without removing or otherwise damaging the strained layer. For example, single crystalline and/or polycrystalline Ge, GeOₓ, Si, and AlAs, as well as photoresist, may be used as a sacrificial layer.

In some applications, it may be beneficial for the chiral structure to include a conductive layer on the elongate strip (i.e., on the strained layer) prior to rolling. The optional conductive layer(s) may comprise one or more high conductivity materials selected from the group consisting of carbon, silver, gold, aluminum, copper, molybdenum, tungsten, zinc, palladium, platinum and nickel. For example, graphene and/or metallic dichalcogenides such as MoS₂, MoSe₂, WS₂ and WSe₂ may be suitable. The conductive layer(s) may include additional tensile strain to facilitate rolling when the sacrificial layer is removed. Advantageously, the conductive layer(s) may be made as thick and smooth as possible to reduce the thin film or sheet resistivity without interfering with the rolling process. The sheet resistivity of the conductive pattern layer(s) may have a significant impact on the performance and size of the rolled-up structure and thus may be kept as low as possible. For example, the sheet resistivity may be about 5 μohm·cm or less.

The conductive layer(s) may have a multilayer structure, such as a Ni—Au—Ni trilayer structure. In such cases, the bottom layer may act as an adhesion layer, the middle layer may act as a conductive layer, and the top layer may act as a passivation/protection layer. Typically, adhesion and passivation layers have a thickness of from about 5-10 nm. It is also contemplated that the conductive layer(s) may comprise a two-dimensional material, such as graphene or transition metal dichalcogenides, e.g., MoS₂ MoSe₂, WSe₂ and/or WS₂. Such two-dimensional materials can be viewed as free-standing atomic planes comprising just a single monolayer or a few monolayers of atoms. For example, the conductive layer may comprise a few monolayers of graphene formed on a strained SiNₓ bilayer, or a single monolayer of graphene may be formed on hexagonal boron nitride, which may replace the strained SiNₓ bilayer. It is also contemplated that the conductive layer may comprise carbon nanotubes (in the form of bundles or an array) that may be grown on, for example, a quartz substrate and then transferred to a strained SiNₓ bilayer for roll-up.

Typically, the conductive layer(s) may have a thickness of at least about 5 nm, at least about 10 nm, at least about 20 nm, at least about 50 nm, at least about 70 nm, or at least about 90 nm. The thickness may also be about 200 nm or less, about 150 nm or less, or about 100 nm or less. For example, the thickness may range from about 10 nm to about 100 nm, or from about 20 nm to about 80 nm. However, in some embodiments, such as those in which the conductive layer comprises a two-dimensional material as discussed above, the thickness may be about 1 nm or less, down to a few monolayers or to one monolayer.

### Impact of Ladder Geometry on Chirality

To explore the geometric effects of chirality control, ladder structures were patterned with varying aspect ratios and rung dimensions/spacings over a parameter space detailed in Table 1. The strip (or film) thickness was held constant at 55 nm LF/20 nm HF. It was found that ladder structures oriented at a misalignment angle of angle 15° (clockwise rotation), relative to a <110> direction (e.g., as shown in FIG. 3B) experienced etching first on the bottom left and top right corners, resulting in left handed double helical configurations. In contrast, ladder structures oriented at a misalignment angle of −15° (counterclockwise rotation) relative to a <110> direction (e.g., as shown in FIG. 3C) experienced etching first on the bottom right and top left corners, resulting in right handed double helical configurations. Highly uniform chiral structures may be achieved from ladder structures with misalignment angles of at least about ±15° , high aspect ratios (b/a≧10), and/or a large rung (tranverse strip) spacing (e≧5 μm).

TABLE 1
Dimensions of Exemplary Ladder Structures (μm)

| | a | b | c | d | e |
|---|---|---|---|---|---|
| 1 | 9 | 200 | 3 | 3 | 15 |
| 2 | 16 | 200 | 6 | 3 | 12 |
| 3 | 17 | 200 | 7 | 3 | 6 |
| 4 | 26 | 200 | 10 | 3 | 6 |
| 5 | 17 | 451 | 5 | 3 | 25 |
| 6 | 15 | 341 | 3 | 3 | 40 |
| 7 | 20 | 204 | 6 | 3 | 20 |

As expected, ladder structures oriented perpendicular to the <110> direction experience nearly symmetric etching and, with the exception of extremely high aspect ratio structures (e.g., b/a≧20), roll into tubes exhibiting no chirality. In this case, regions near the rungs etch slowly and are the last points of contact before full release of the strips, resulting in symmetric rolling. Chiral uniformity among ladder structures of different aspect ratios decreases when the misalignment angle deviates from 15°. Beyond a ±3° tolerance, aspect ratio appears to be the dominant chirality control factor. Owing primarily to a greater torque before full release, high aspect ratio ladder structures, which are long and narrow, are more likely to form double helical structures, whereas shorter, wider ladder structures more often exhibited no chirality. Longer ladder structures with a larger rung spacing (e≧5 μm) are most consistent with predictions for obtaining helical structures from a single high aspect ratio rectangular strip, due to the high aspect ratio between ladder rungs. Short, wide ladder structures suffer from buckling ladder rungs, inducing an additional strain vector and reducing the overall torque. Because of this, random rolling behavior was observed in ladders having a lower aspect ratio (b/a≦8) and long rungs (c≧7 μm) with narrow spacing (e≦6 μm) over all offset angles. Additionally, at offset angles less than 10°, low aspect ratio ladders exhibited no chirality, while higher aspect ratio ladders at the same offset angle rolled normally. The formation of double helical structures, enabled by the amorphous SiNₓ membranes through anisotropic release, could lead to unique Janus architectures if functional structures or materials can be patterned in 2D before release.

### Fabrication Method

A method of making a rolled-up structure, such as a chiral structure, may entail forming an elongate strip on a supporting surface of a substrate. The elongate strip may comprise an amorphous or polycrystalline material and may include an upper portion under tensile stress and a lower portion nearer to the substrate under compressive stress. A portion of the substrate is etched, thereby releasing an end of the elongate strip and allowing the elongate strip to roll up to relieve strain. A rolled-up chiral structure may be formed comprising the elongate strip in a rolled configuration about a longitudinal axis, where the rolled configuration is a helical configuration comprising a non-zero helix angle. The longitudinal axis of the rolled configuration is substantially parallel to the supporting surface.

The substrate and the elongate strip may have any of the characteristics described in the present disclosure, and these characteristics may influence or predetermine the chirality of the rolled-up chiral structure. For example, the substrate may be a single crystal substrate comprising a crystallographic plane oriented parallel to the supporting surface and comprising a preferred etch direction. In such an embodiment, a rolling direction of the rolled configuration may be substantially parallel to the preferred etch direction, and the chirality of the chiral structure may be determined by the orientation of the elongate strip on the supporting surface of the substrate prior to rolling. In another example, the substrate may be an amorphous substrate, and the chirality may be influenced by the length-to-width ratio (aspect ratio) of the elongate strip. As discussed above, high aspect ratio elongate strips (e.g., elongate strips having an aspect ratio of greater than 3:1) may achieve more predictable chirality. In one particular embodiment, the elongate strip may comprise amorphous SiNₓ, where x is from about 0.5 to about 1.5.

Forming the elongate strip may entail first depositing two oppositely strained sublayers to form a strained layer that may have a predetermined amount and distribution of internal strain. Any of a number of deposition methods known in the art, such as physical vapor deposition or chemical vapor deposition, may be employed to form the strained layer. A mixed-frequency PECVD process may allow control over both compressive- and tensile-strained sublayers, as described previously.

Deposition of the strained layer may be followed by lithography and etching methods known in the art to form an elongate strip of the desired geometry and size from the strained layer.

The etching of the portion of the substrate (which may comprise a sacrificial layer) to induce roll-up of the elongate strip may be carried out using wet or dry etching with an appropriate etchant. Advantageously, the etchant is selected such that an etch rate of the substrate and/or sacrificial layer is at least about 1000 times an etch rate of the elongate strip. A high etch selectivity as described above to ensure that the elongate strip is not significantly etched during removal of the portion of the substrate/sacrificial layer. In the case of SiNₓ deposited on a silicon substrate, for example, suitable etchants may include hydroxide based solutions, such as KOH.

If a conductive layer is desired on the elongate strip, it may be formed by depositing a metal thin film on the strained layer by a vapor deposition method such as sputtering or evaporation. If desired, the metal thin film may be patterned using lithography and etching steps known in the art to create a desired geometric pattern.

### Deposition Conditions for SiNₓ

SiNₓ microtubes have been demonstrated using a single layer deposited in a silane (SiH₄)/nitrogen (N₂)/helium (He) PECVD system at high frequency, low temperature, and high power (99 W). This experiment shows that high frequency silicon nitride develops a strain gradient through condensation of the film, as well as through a thermal mismatch with the sacrificial layer/substrate, producing tensile strain on the top of the film and compressive strain on the bottom. By using a mixed-frequency PECVD process, control is permitted over both compressive- and tensile-strained components individually. Three types of strain can be produced in the strained layer: tensile, compressive, and compensated (zero) stress. Compressive stress is generated at high power and low frequency (LF), and is volumetrically denser than its low power high frequency (HF) counterpart. Depending on the deposition parameters (such as pressure, gas flow ratio and rate, substrate temperature, and RF power and frequency), SiNₓ films deposited using NH₃/SiH₄/N₂ can show a range of densities from 2-2.5 mg/cm³ and refractive indexes from 1.8-2.35. The density and refractive index are known to be good indicators of the amount of stress embedded in the strained layer. Producing low hydrogen content films removes a degree of freedom to post-roll processing. Unique to SiNₓ thin films using ammonia(NH₃)/silane (SiH₄)/nitrogen (N₂) plasmas, a high amount of amine fragments are embedded in the layer. This may result in a Young's modulus nearly half that of the bulk film and an opportunity to augment the thin film's thickness, composition, and strain after rolling into a tubular structure via ammonia and hydrogen outdiffusion.

### Etching Parameters for SiNₓ

The etch rate of the (110) plane relative to the (100) and (111) planes in a polar KOH solution has been considered. Anisotropy of KOH etchants varies inversely with temperature, with the ratio of 160:100:1 (<110>:<100>:<111>) at room temperature, decreasing to 50:30:1 at 100° C. The etch rate for a Si (100) substrate using 45% KOH etching solution at 47° C. is 272 nm/min laterally and 316 nm/min vertically, resulting in rolled structures suspended on a tall pedestal. However for a (111) substrate, because the (111) plane is extremely slow etching, the lateral (110) plane takes priority making it possible to achieve 380 nm/min lateral etching with only 4 nm/min vertical advancement. Arrays of rectangular-shaped ladder-like SiNₓ bilayers deposited on Si (111) substrates and oriented within a range of angles exhibit predictable chirality when released.

The partially etched (111) silicon substrate can be inspected at periodic points during etching to predict rolling behavior. It has been observed that partially etched ladders remain intact longest near the inside corners at the ladder rungs. This appears to cause ladder structures with wide rungs (c≧7 μm) to have unpredictable chirality under most or all rotation angles. Additionally, chirality uniformity decreases as the misalignment angle diverges from 15°, and this is most noticeable in low aspect ratio ladder structures.

Stoichiometric silicon nitride shows very little to no activity in BOE or KOH. However, the non-stoichiometric, silicon-rich PECVD silicon nitride used to create elongate strips including a strain gradient may leave the rolled structure more susceptible to attack from available sacrificial layer etchants that target Si—H and Si—Si bonds, such as hydroxide-based solutions. This effect is not noticed at room temperature as much as it is at 47° C. and thick low frequency layers, suggesting that the high frequency layer is being attacked. This may reduce the tensile layer thickness and the amount of accommodated stress, relaxing the tube to a larger diameter. Inversely, if the compressive layer were thinning, the tube diameter would be expected to decrease. It has also been observed that the etch ratio of HF:LF silicon nitride in BOE, deposited using the parameters mentioned previously, goes to ˜2:1, indicating that it may not be possible to use BOE to properly define an upwards rolling tube. However, if it was desired to make tubes that rolled downward (tensile layer on bottom), this ratio may be beneficial by reducing the amount of overetching experienced by the top layer while better defining the bottom layer.

### Curvature Modulation

Local curvature modulation in the rolled-up structures due to thickness or stress variation can also be used to create unique 3D hierarchical architectures. This can be achieved through either pre-rolling fabrication steps or post-rolling thermal processing. For example, thickness variations can be created in high aspect ratio structures by forcing a strip to overlap itself as it is released from the substrate. As shown for example in FIG. 4, a high aspect ratio ladder structure (a=17 μm, b=451 μm, c=5 μm, d=3 μm, and e=25 μm) may be patterned onto a 39 nm LF/20 nm HF SiNₓ bilayer and offset at 10° to the left, relative to the <110> direction to achieve an overlapping chiral structure, improving rigidity. In addition, the turn-to-turn overlap distance can be modulated within the same rolled structure (overlap is seen as bright areas in SEM). This can be useful in achieving large bandwidth RF components, as each overlapping area has different capacitance and inductance. Strain gradients resulting from additional thin films deposited on the elongate strip can also be used as a pre-rolling curvature modulation technique. Application of additional films with different internal stress or thickness may also result in a diameter change and can be used to achieve coaxial and triaxial architectures.

### Curvature Control Via Post-Rolling Anneal

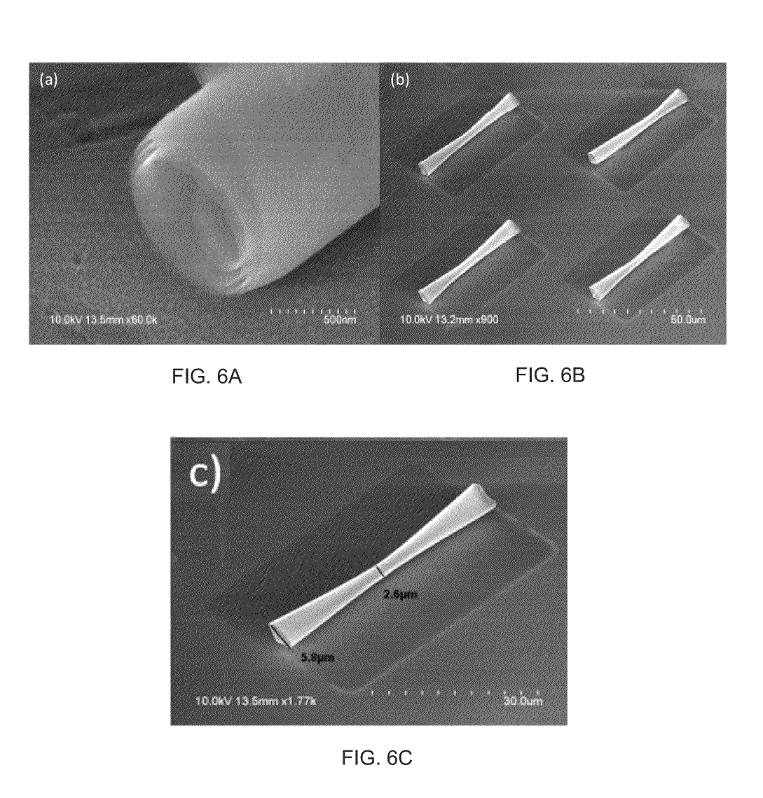

In addition, curvature variations can be engineered through post-rolling thermal processing. The diameter of a rolled-up structure (which may or may not include any chirality) can be reduced when subjected to thermal annealing at a temperature above the deposition temperature (e.g., greater than about 300° C. for SiNₓ). For a SiNₓ strained layer deposited using a SiH₄ and NH₃ mixture, the diameter reduction during annealing may be due to NH₃ outdiffusion. As shown in FIG. 6C for an exemplary rolled-up SiNₓ sheet, a 60 s anneal at 600° C. in a N₂ atmosphere results in as much as a 200% reduction in diameter locally, specifically at the center of the rolled-up structure relative to the ends, resulting in a graduated cone architecture. The diameter and length of the rolled-up structure prior to annealing were 5.8 μm and about 50 μm, respectively. It is believed that the uneven reduction in diameter along the tube is a result of a local thermal gradient along the microtube axis, where heat is trapped in the center and more dissipation occurs at the ends. Depending on the length of the tube and local thermal engineering, various unique structures can be created using this mechanism. Locally constrained tubular structures may be useful as low pass filters in microfluidic channels, where channel radius has a large impact on the inertia and friction experienced by the fluid.

In another example of curvature control via annealing, a rapid thermal anneal (RTA) carried out above the deposition temperature reduced a single-turn 4.6 μm diameter tubular structure nearly 83% to achieve a tubular structure of less than 800 nm in inner diameter with approximately three turns, as shown in FIG. 6A. To produce these uniform rolled structures, a rest period of 5 seconds is employed between temperature rises during the RTA. To produce tapered tubes in which the diameter of the rolled-up structure is reduced locally (as opposed to uniformly along the length), as shown for example in FIGS. 6B and 6C, a non-thermal equilibrium RTA may be employed in which there are no rest periods between temperature ramps. The exemplary tapered tubes of FIGS. 6B and 6C have about a 2:1 diameter ratio from the ends to the center. Other ratios, such as 1.5:1 or greater, 2:1 or greater, 2.5:1 or greater, or 3:1 or greater, are also possible.

To produce SiNₓ rolled structures having a reduced diameter that is uniform along the length of the tube, the anneal, which may be a RTA, may entail a series of increases to a temperature in the range of 500° C. to 700° C. with a brief rest period between each increase, to allow the structure to equilibrate during heating. The rest periods may last about 5 seconds, and the temperature may be increased at a rate of 8-10° C./second. To produce SiNₓ rolled structures having a reduced diameter in a local region along the length of the tube, a nonequilibrium anneal (which may be an RTA) may be carried out to a temperature in the range of 500° C. to 700° C. at a rate of 10-12° C./second without rest periods during the rise.

The overall reactions for a SiNₓ thin film deposited using an NH₃/SiH₄/N₂ plasma and annealed post-roll-up are:

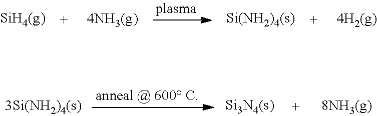

The post-roll-up annealing process offers a means to achieve reduced inner diameters compared to as-rolled inner diameters, which depend on the thickness of the strained layer prior to rolling and the internal strain, as explained above. Accordingly, the annealing process enables a rolled configuration of a sheet (or elongate strip) to have a reduced inner diameter for a given sheet or strip thickness. After annealing, the rolled-up structure may comprise a sheet in a rolled configuration about a longitudinal axis, where the sheet comprises a thickness t and the rolled configuration comprises an inner diameter D, and where an inner diameter-to-thickness ratio D/t is no greater than about 40. The inner diameter-to-thickness ratio D/t may also be no greater than about 25. The rolled configuration may be a tubular configuration or a helical configuration having any of the characteristics described above.

The inner diameter D may be substantially uniform along the length of the rolled configuration. Alternatively, depending on the annealing treatment as discussed above, the inner diameter D may be nonuniform along the length of the rolled configuration. In such a case, the inner diameter-to-thickness ratio D/t may be calculated using a minimum inner diameter Dₘᵢₙ of the rolled configuration. Such a structure may be described as a tapered rolled-up structure, or as having a tapered rolled configuration, as shown for example in FIGS. 6B and 6C. The sheet or elongate strip that forms the rolled-up structure may have any of the characteristics set forth above for the elongate strip. For example, the sheet or elongate strip may comprise an amorphous or a polycrystalline material. In one embodiment, the sheet or elongate strip may amorphous SiNₓ, where x is from about 0.5 to about 1.5.

### Finite Element Simulation Approach for Chiral Structure

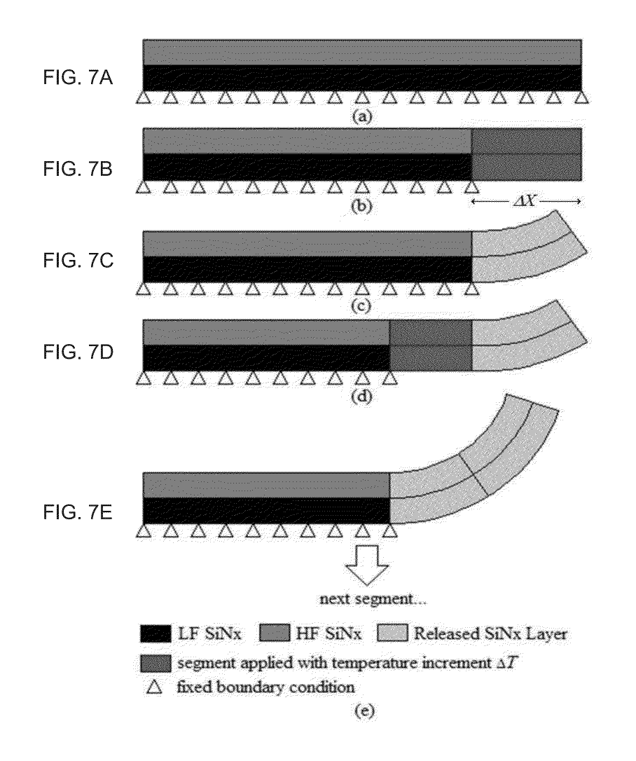

A silicon nitride (SiNₓ) bilayer structure is studied here as a model system for finite element simulations. The bilayer structure includes a bottom low frequency (LF) SiNₓ layer (under compressive stress before releasing from constraint) and a top high frequency (HF) SiNₓ layer (under tensile stress before releasing from constraint), as shown in FIGS. 7A-7E.

Initially a fixed boundary condition is applied to all nodes at the bottom of the LF SiNₓ layer to model the effect of the sacrificial layer. The materials are assumed to be isotropic and linear elastic since the proposed FEM modeling stays in the elastic region but is modeled with geometric nonlinearities due to the large deformation. A shell element is used to model multiple-layer structures, and its accuracy in modeling composite shells is governed by the Mindlin-Reissner shell theory. Different thicknesses and material properties are assigned to each layer. The Young's modulus E for both PECVD LF SiNₓ and HF SiNₓ thin films with similar growth conditions is reported to be 210 GPa. The Poisson coefficient is chosen to be 0.28 for both LF SiNₓ and HF SiNₓ thin films in the simulation, and the residual stresses of both LF SiNₓ and HF SiNₓ are modeled by a fictitious thermal expansion. The same temperature increment is assigned to the nodes of all shell elements. To simulate the compressive and tensile stresses, different coefficients of thermal expansion are assigned to the LF SiNₓ and HF SiNₓ layers. The pre-measured residual stresses of each layer by a FSM 500TC metrology tool can then be induced by applying a proper temperature increment such that the measured residual stresses for each thin film layer are achieved. The thermal coefficient of LF SiNₓ is taken from literature. The fictitious temperature increment of LF SiNx is then determined to be 1450° C. to achieve the measured value of residual stress in LF SiNₓ. For other materials listed in Table 2, their thermal coefficients are fitted for each material to reach its respective measured residual stress level when the fictitious temperature increment is fixed at 1450° C.

TABLE 2
Material Properties in FEM Simulations

| | | | | Thermal | |
|---|---|---|---|---|---|
| | Residual | Young's | Poisson | Expansion | Temperature |
| Sub- | stress | Modulus | Coeffi- | Coefficient | increment |
| layer | (MPa) | (GPa) | cient | (1/° C.) | (° C.) |
| LF SiNₓ | −1133 | 210 | 0.28 | 2.75 × 10⁻⁶ | 1450 |
| HF SiNₓ | +387 | 210 | 0.28 | −9.61 × 10⁻⁷ | 1450 |

*signs − and + for the residual stress denote the compressive and tensile stresses, respectively

A moving boundary condition is used to model the etching of the sacrificial layer. The rolling process of the strained membrane is a non-linear, large deformation transient quasi-dynamic process. This process is simulated by a series of FEM simulations of static deformation by releasing the constraints on the bottom segments in sequence. In the simulations, the length of each segment is set to be less than 1/200 of the circumference of the first turn. To apply the moving boundary condition, a simulation loop shown in FIGS. 7A-7E is realized. The loop starts from FIG. 7A by applying a fixed boundary condition at the bottom of the bilayer to model the sacrificial layer. In the next step, shown in FIG. 7B, the constraint on the first segment ΔX is released and a fictitious temperature increment ΔT=1450° C. is applied to all nodes associated with this segment. After that, static simulation is performed to obtain an updated geometry shown in FIG. 7C. By repeating the loop, the next segment is released and the same temperature increment ΔT is applied to obtain the next updated geometry as shown in FIG. 7D. The loop repeats until the last segment is released. The FEM program ANSYS is used for the numerical simulations.

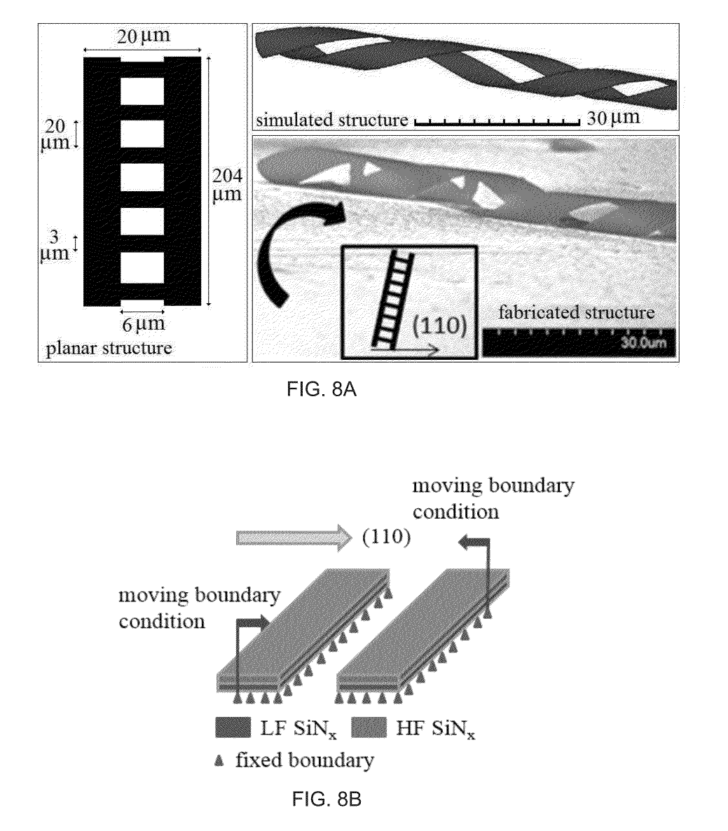

Complicated three-dimensional structures, such as chiral structures, can be simulated by controlling the moving boundary conditions to mimic the actual anisotropic etching process. FIG. 8A shows the design of a ladder-shaped structure comprising SiNₓ with dimensions shown in the left hand schematic. It is placed on top of a single crystal silicon sacrificial layer oriented at an angle of 15° clockwise relative to the (110) facets (or <110> direction). Anisotropic etching of the sacrificial layer leads to etching of the bottom left and top right corners first, and finally results in a left-handed double helical structure. In the FEM modeling, the anisotropic etching process can be represented by moving the fixed boundary conditions along the direction of etching of the sacrificial layer as shown in FIG. 8B, i.e., the front of the fixed boundary in the simulation lies in the direction 15° relative to the (110) facets. The simulation follows the same loop illustrated above. Since the ladder rungs have the same curvature as the rest of the elongate strip and play a minor role in the shape change, they are not considered in the current FEM model. Referring to FIG. 8A, the simulated rolled-up structure (upper right) shows good agreement with the experimental results (lower right).

Although the present invention has been described in considerable detail with reference to certain embodiments thereof, other embodiments are possible without departing from the present invention. The spirit and scope of the appended claims should not be limited, therefore, to the description of the preferred embodiments contained herein. All embodiments that come within the meaning of the claims, either literally or by equivalence, are intended to be embraced therein. Furthermore, the advantages described above are not necessarily the only advantages of the invention, and it is not necessarily expected that all of the described advantages will be achieved with every embodiment of the invention.

What is claimed is:

1. A chiral structure comprising:
an elongate strip in a rolled configuration about a longitudinal axis, the rolled configuration being a helical configuration comprising a non-zero helix angle, the elongate strip comprising an amorphous or a polycrystalline material.

2. The chiral structure of claim 1, wherein a supporting surface of a substrate underlies the elongate strip, the longitudinal axis of the rolled configuration being substantially parallel to the supporting surface.

3. The chiral structure of claim 2, wherein the substrate is a single crystal substrate comprising a crystallographic plane oriented parallel to the supporting surface.

4. The chiral structure of claim 3, wherein the crystallographic plane comprises a preferred etch direction, and wherein a rolling direction of the rolled configuration is substantially parallel to the preferred etch direction.

5. The chiral structure of claim 4, wherein the crystallographic plane is selected from the {111} family of planes, and wherein the preferred etch direction is a <110> direction.

6. The chiral structure of claim 2, wherein the substrate is an amorphous substrate and the elongate strip has a length-to-width ratio of greater than about 3:1.

7. The chiral structure of claim 1, wherein the helix angle is from about 10° to about 20°.

8. The chiral structure of claim 1, wherein the elongate strip comprises a thickness of no greater than about 1 micron.

9. The chiral structure of claim 1, wherein the elongate strip comprises amorphous SiNₓ, where x is from about 0.5 to about 1.5.

10. The chiral structure of claim 1 comprising two of the elongate strips connected by a series of transverse strips, thereby comprising a ladder structure, the rolled configuration of the ladder structure comprising a double helical configuration.

11. The chiral structure of claim 10, wherein the ladder structure comprises a length-to-width ratio of greater than about 9:1.

12. A method of making a chiral structure, the method comprising:
forming an elongate strip on a supporting surface of a substrate, the elongate strip comprising an amorphous or polycrystalline material and including an upper portion under tensile stress and a lower portion under compressive stress, the lower portion being nearer to the substrate;
etching a portion of the substrate, thereby releasing an end of the elongate strip and allowing the elongate strip to roll up to relieve strain, and
forming a rolled-up chiral structure comprising the elongate strip in a rolled configuration about a longitudinal axis, the rolled configuration being a helical configuration comprising a non-zero helix angle, and the longitudinal axis being substantially parallel to the supporting surface.

13. The method of claim 12, wherein the substrate is a single crystal substrate comprising a crystallographic plane oriented parallel to the supporting surface and comprising a preferred etch direction, and wherein a rolling direction of the rolled configuration is substantially parallel to the preferred etch direction.

14. The method of claim 12, wherein the substrate is an amorphous substrate and the elongate strip has a length-to-width ratio of greater than about 3:1.

15. The method of claim 12, wherein the elongate strip comprises amorphous SiNₓ, where x is from about 0.5 to about 1.5.

16. The method of claim 12, wherein an etch rate of the substrate is at least about 1000 times an etch rate of the elongate strip.

17. The method of claim 12, wherein the substrate comprises a sacrificial layer thereon, and wherein etching the portion of the substrate comprises etching the sacrificial layer, the sacrificial layer comprising an etch rate at least about 1000 times an etch rate of the elongate strip.

18. The method of claim 12, further comprising, after forming the rolled-up chiral structure, annealing the rolled-up chiral structure.

19. A rolled-up structure with modulated curvature, the rolled-up structure comprising:
a sheet comprising an amorphous or polycrystalline material in a rolled configuration about a longitudinal axis, the sheet comprising a thickness t and the rolled configuration comprising an inner diameter D, wherein an inner diameter-to-thickness ratio D/t is no greater than about 40.

20. The rolled-up structure of claim 19, wherein the inner diameter-to-thickness ratio D/t is no greater than about 25.

21. The rolled-up structure of claim 19 wherein the inner diameter D is substantially uniform along a length of the rolled configuration.

22. The rolled-up structure of claim 19 wherein the inner diameter D is nonuniform along a length of the rolled configuration, and wherein the inner diameter-to-thickness ratio D/t is calculated using a minimum inner diameter Dₘᵢₙ of the rolled-up structure.

23. The rolled-up structure of claim 19, wherein the sheet comprises amorphous SiNₓ, where x is from about 0.5 to about 1.5.
